(19) United States
(12) Patent Application Publication
(10) Pub. No.: US 2002/0074540 A1
(43) Pub. Date: Jun. 20, 2002

(54) CONTACT STRUCTURE IN SEMICONDUCTOR INTEGRATED CIRCUIT AND METHOD FOR FORMING THE SAME

(76) Inventor: HIROAKI YOKOYAMA, TOKYO (JP)

Correspondence Address: HAYES SOLOWAY HENNESSEY GROSSMAN, & HAGE, 175 CANAL STREET, MANCHESTER, NH, 03101

(21) Appl. No.: 08/992,767

(22) Filed: Dec. 17, 1997

(30) Foreign Application Priority Data
Dec. 18, 1996 (JP) 8-338403

(51) Int. Cl. H01L 47/00

(52) U.S. Cl. 257/1

(57) ABSTRACT

In a semiconductor device including a large-diameter contact hole and a small-diameter contact hole which are formed to penetrate through an insulator film formed on a semiconductor substrate, the small-diameter contact hole is completely filled with a refractory conductive material, and the large-diameter contact hole has a sidewall formed of the refractory conductive material on a side surface of the large-diameter contact hole. The sidewall covers the side surface lower than a position which is lower than an upper end of the large-diameter contact hole by a predetermined distance. Thus, a small and stable contact resistance can be realized both in the large-diameter contact hole and in the small-diameter contact hole

### BACKGROUND OF THE INVENTION

1. Field of the Invention

The present invention relates to a semiconductor device and a method for manufacturing the same, and more specifically to a contact structure in a semiconductor integrated circuit and a method for forming the contact structure.

2. Description of Related Art

One typical method widely known at present, for forming a contact electrode for use in a semiconductor integrated circuit, utilizes a sputtering of an Al-Si-Cu alloy or an aluminum simple substance. Now, the typical method for forming the contact electrode will be explained with reference to FIGS. 1A and 1B.

First, as shown in FIG. 1A, a silicon oxide film 2 having a thickness of about 1 μm is deposited on a principal surface of a silicon substrate 1 by a CVD (chemical vapor deposition) process. Then, as shown in FIG. 1A, a contact hole 9 is formed to penetrate through the silicon oxide film 2 formed on the principal surface of the silicon substrate 1, by use of a photolithography and an etching.

Thereafter, as shown in FIG. 1B, an aluminum layer 8 having a thickness of about 1 μm and constituting a wiring conductor layer, is formed to cover the whole surface of the silicon substrate 1 by means of a sputtering. This aluminum layer 8 can be replaced with an Al-Si-Cu alloy layer.

Recently, with advanced high integrated density and highly fine patterning of the semiconductor integrated circuit, there is a strong inclination that the contact hole becomes small, with the result that the prior art contact electrode forming method as shown in FIGS. 1A and 1B is becoming difficult to form a contact electrode having a good contact resistance.

An improved method for solving this problem is proposed by Japanese Patent Application Pre-examination Publication No. JP-A-62-213120 (the content of which is incorporated by reference in its entirety into this application, and also an English abstract of JP-A-62-213120 is available from the Japanese Patent Office and the content of the English abstract of JP-A-62-213120 is also incorporated by reference in its entirety into this application). Now, this improved method for forming the contact electrode will be explained with reference to FIGS. 2A to 2C.

The process is the same as the first mentioned prior art process until the contact hole 9 is formed as shown in FIG. 1A.

Thereafter, as shown in FIG. 2A, a refractory metal layer 5 is deposited on the whole surface of the silicon substrate 1 by use of the CVD process or a PVD (physical vapor deposition) process. The refractory metal layer 5 is formed of a simple substance or an alloy of a refractory metal, but can be formed of a silicide of a refractory metal such as Mo or W. In addition, if the CVD process is used, it is preferred to use a low pressure CVD process exerting an excellent coverage.

Then, a reactive ion etching (RIE) is conducted to the whole surface of the silicon substrate 1 in a chlorine gas atmosphere, so that a sidewall 6 of the refractory metal remains only on a side surface of the contact hole 9, as shown in FIG. 2B. The RIE process is an anisotropic etching so that the etching is advanced only in a direction perpendicular to the silicon substrate 1, with the result that the refractory metal remains only on the side surface of the contact hole 9 where the refractory metal thickness in the vertical direction is large.

In addition, the etching conducted by means of the RIE process is conducted for the purpose of removing the refractory metal 5 from the surface of the substrate 1 where the remains of the refractory metal is inconvenient for forming the device. Therefore, if the refractory metal remains on a portion of the contact hole 9, for example, a bottom of the contact hole, other than the sidewall of the contact hole, it is not inconvenient at all. Furthermore, a shoulder of the sidewall 6 of the refractory metal is rounded by action of the RIE process. This is effective in improving the coverage of Al deposited in a next step.

In the next step, as shown in FIG. 2C, an aluminum layer 8 having a thickness of about 1 μm and constituting a wiring conductor layer, is formed to cover the whole surface of the silicon substrate 1 by means of a sputtering. This aluminum layer 8 can be replaced with an Al-Si-Cu alloy layer.

As mentioned above, the prior art contact electrode forming method as shown in FIGS. 1A and 1B is disadvantageous since it becomes difficult to form a contact electrode having a good contact resistance.

The reason for this is as follows: With advancement of the high integrated density and the highly fine patterning of the semiconductor integrated circuit, if an underlying layer is not planarized at the time of patterning each wiring conductor layer, the patterning cannot be realized as a design. For example, a short-circuiting or an open-circuiting of the wiring conductor occurs. The planarization is ordinarily conducted by depositing a relatively thick insulator film and by etching back the deposited insulator film. However, if this planarizing method is used, the thickness of an interlayer insulator film before a contact hole is formed, becomes very large as a matter of course. As a result, when a fine contact hole is formed, even if the sidewall of the refractory metal is formed on the side surface of the contact hole as the prior art process shown in FIGS. 2A to 2C, the aluminum wiring conductor disconnects at a bottom of the contact hole, because the aspect ratio of an actually remaining hole defined by the sidewall becomes noticeably larger than that of the original hole by the side surface of the contact hole before the sidewall is formed. Since the sidewall of the refractory metal exists, the contact electrode never becomes an open-circuiting. However, since the sidewall is in direct contact with the underlying substrate with only one half to one third of a bottom area of the original contact hole before the sidewall is formed, and on the other hand, since a resistance of the refractory metal is higher than that of aluminum, the contact resistance becomes high.

In addition, the semiconductor integrated circuit includes not only large-diameter contact holes but also small-diameter contact holes. However, the prior art contact electrode forming method is difficult to obtain a stable contact resistance both in the large-diameter contact holes and in the small-diameter contact holes. The reason for this is as follows:

For example, when the sidewall of the refractory metal is formed to fit with the small-diameter contact holes, it is necessary to form the refractory metal layer having a thin film thickness to ensure that the small-diameter contact holes are never completely filled by the refractory metal. However, if the refractory metal layer having the thin film thickness is formed, the film thickness of the sidewall of the refractory metal in the large-diameter contact holes becomes too thin, so that the aluminum wiring conductor layer will disconnect at the bottom of the contact hole, with the result that the contact resistance becomes high.

### SUMMARY OF THE INVENTION

Accordingly, it is an object of the present invention to provide a contact structure in a semiconductor integrated circuit and a method for forming the contact structure, which have overcome the above mentioned defect of the conventional one.

Another object of the present invention is to provide a contact structure in a semiconductor integrated circuit and a method for forming the contact structure, capable of obtaining a stable low contact resistance not only in a large-diameter contact hole but also in a small-diameter contact hole, which are mixedly included a semiconductor integrated circuit, by realizing a good contact resistance in a fine contact hole.

The above and other objects of the present invention are achieved in accordance with the present invention by a semiconductor device including a large-diameter contact hole and a small-diameter contact hole formed to penetrate through an insulator film formed on a conductive portion to reach the conductive portion, the small-diameter contact hole being completely filled with a plug of a refractory conductive material, and the large-diameter contact hole having a sidewall formed of the refractory conductive material on a side surface of the large-diameter contact hole, the sidewall covering the side surface lower than a position which is lower than an upper end of the large-diameter contact hole by a predetermined distance, a wiring conductor layer being deposited on the insulator film to cover a top surface of the plug of the refractory conductive material, and to fill a space remaining in the large-diameter contact hole thereby to cover a bottom of the large-diameter contact hole and a surface of the sidewall of the refractory conductive material within the large-diameter contact hole.

Here, it is defined that the large-diameter contact hole has an aspect ratio of not greater than 2, and the small-diameter contact hole has an aspect ratio of greater than 2.

According to another aspect of the present invention, there is provided a method for manufacturing a semiconductor device including the step of forming a large-diameter contact hole and a small-diameter contact hole to penetrate through an insulator film formed on a conductive portion to reach the conductive portion; depositing a refractory conductive material to cover the whole surface of the insulator film including the large-diameter contact hole and the small-diameter contact hole; etching back the deposited refractory conductive material to expose only an upper surface of the insulator film and a bottom and an upper end portion of the large-diameter contact hole, so that the small-diameter contact hole is completely filled with a plug of the refractory conductive material, and in the large-diameter contact hole, a sidewall formed of the refractory conductive material covers a side surface of the large-diameter contact hole lower than a position which is lower than an upper end of the large-diameter contact hole by a predetermined distance; and depositing a wiring conductor layer on the insulator film to cover a top surface of the plug of the refractory conductive material, and to fill a space remaining in the large-diameter contact hole thereby to cover the exposed bottom of the large-diameter contact hole and a surface of the sidewall of the refractory conductive material within the large-diameter contact hole

For example, the refractory conductive material can be formed of a refractory metal or a silicide of the refractory metal. On the other hand, the conductive portion can be either a semiconductor substrate if the insulator film directly covers the semiconductor substrate, or a lower-level wiring conductor if the insulator film is an interlayer insulator film covering the lower-level wiring conductor.

As seen from the above, according to the present invention, the small-diameter contact hole is completely filled with the plug of the refractory conductive material, and in the large-diameter contact hole, on the other hand, the sidewall formed of the refractory conductive material covers the side surface of the large-diameter contact hole lower than the position which is lower than the upper end of the large-diameter contact hole by the predetermined distance.

With this arrangement, even if the interlayer insulator film becomes thick or even if the contact hole becomes fine because of the advanced high integrated density and highly fine patterning of the semiconductor integrated circuit, the wiring conductor layer (such as a aluminum layer) never disconnect at the bottom of the contact hole, with the result that the contact resistance is stable and low.

Since the small-diameter contact hole is completely filled with the plug of the refractory conductive material, the sidewall of the refractory conductive material formed on the side surface of the large-diameter contact hole can be thickened to a degree sufficient to prevent the wiring conductor layer (such as a aluminum layer) deposited in a later step from disconnecting at the bottom of the contact hole. Furthermore, since the sidewall of the refractory conductive material is formed to cover the side surface of the large-diameter contact hole lower than the position which is lower than the upper end of the large-diameter contact hole by the predetermined distance, the wiring conductor layer (such as a aluminum layer) becomes difficult to cause disconnection even if the interlayer insulator film becomes thick because of the advanced high integrated density and highly fine patterning of the semiconductor integrated circuit, because a hole defined by the sidewall and the exposed upper side surface of the contact hole has an upper end diameter larger than a bottom diameter, in other words, has a general shape which may be called a reverse-truncated cone. From a different viewpoint, it can be said that the hole defined by the sidewall and the exposed upper side surface of the contact hole has an apparent aspect ratio improved or reduced in comparison with the prior art as shown in FIG. 2B in which the sidewall reaches the upper end of the contact hole, with the result that the wiring conductor layer deposited in a later step is prevented from disconnecting at the bottom of the hole defined by the sidewall. For this purpose, the predetermined distance as mentioned above is required between the upper end of the contact hole and the upper end of the sidewall, and is preferably not less than 10% but not greater than 40% of the thickness of the insulator film through which the contact hole concerned is formed to penetrate. In the large-diameter contact hole, as a result, since the wiring conductor layer is surely connected directly to the conductive portion, the wiring conductor layer is connected to the underlying conductive portion with a low and stable contact resistance.

On the other hand, since the small-diameter contact hole is completely filled with the plug of the refractory conductive material, the plug of the refractory conductive material is in direct contact with the underlying conductive layer with all the bottom area of the small-diameter contact hole. Therefore, even if the wiring conductor layer is connected through the plug of the refractory conductive material to the underlying conductive layer, and even if a resistance of the refractory conductive material is higher than that of the wiring conductor layer, the wiring conductor layer is connected to the underlying conductive layer with a low and stable contact resistance.

Therefore, a small and stable contact resistance can be realized both in the large-diameter contact hole and in the small-diameter contact hole.

The above and other objects, features and advantages of the present invention will be apparent from the following description of preferred embodiments of the invention with reference to the accompanying drawings.

### BRIEF DESCRIPTION OF THE DRAWINGS

FIGS. 1A and 1B are diagrammatic sectional views illustrating a prior art method for forming the contact electrode;

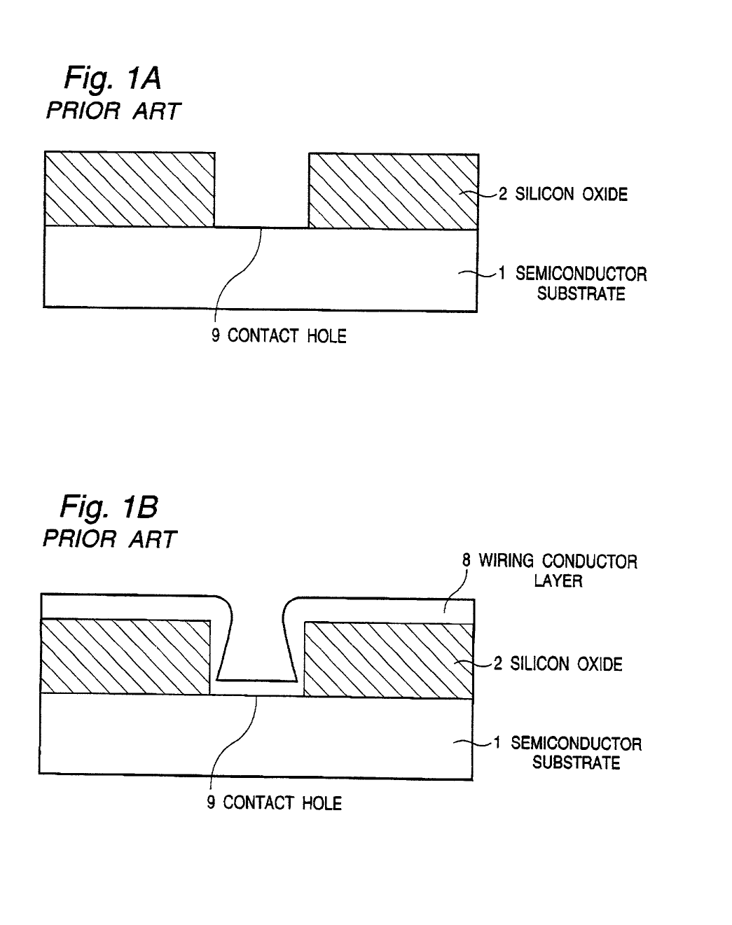

FIGS. 2A to 2C are diagrammatic sectional views illustrating another prior art method for forming the contact electrode;

FIG. 3 is a diagrammatic sectional view illustrating of a first embodiment of the contact structure in the semiconductor integrated circuit in accordance with the present invention;

FIGS. 4A to 4D are diagrammatic sectional views illustrating a first embodiment of the method for forming the contact structure in accordance with the present invention;

FIG. 5 is a diagrammatic sectional view illustrating of a second embodiment of the contact structure in the semiconductor integrated circuit in accordance with the present invention; and

FIGS. 6A to 6C are diagrammatic sectional views illustrating a second embodiment of the method for forming the contact structure in accordance with the present invention.

### DESCRIPTION OF THE PREFERRED EMBODIMENTS

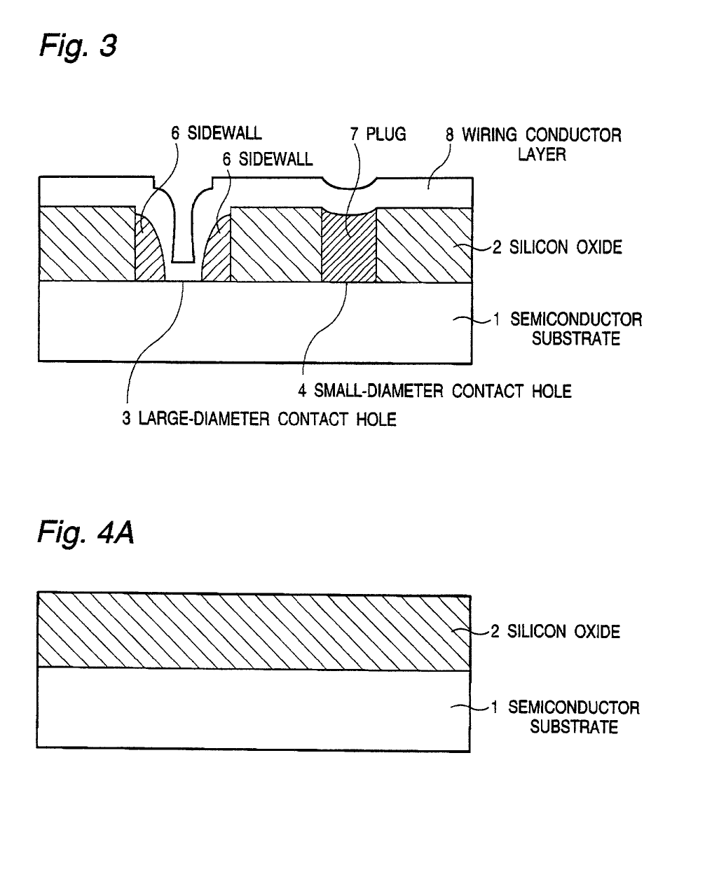

Referring to FIG. 3, there is shown a diagrammatic sectional view illustrating of a first embodiment of the contact structure in the semiconductor integrated circuit in accordance with the present invention, which mixedly includes a large-diameter contact hole and a small-diameter contact hole formed to penetrate through an insulator film formed on a semiconductor substrate,

As shown in FIG. 3, the semiconductor integrated circuit includes a semiconductor substrate 1, an insulator film 2 formed on a semiconductor substrate 1, a large-diameter contact hole 3 formed to penetrate through the insulator film 2 and a small-diameter contact hole 4 formed to penetrate through the insulator film 2. The small-diameter contact hole 4 is completely filled with a plug 7 of a refractory conductive material. In the large-diameter contact hole 3, on the other hand, a sidewall 6 formed of the refractory conductive material covers a side surface of the large-diameter contact hole 3 lower than a position which is lower than a position which is lower than an upper end of the large-diameter contact hole by a predetermined distance. The refractory conductive material is either a refractory metal or a silicide of the refractor metal. A wiring conductor layer 8 (formed of for example aluminum) is deposited on the whole surface of the semiconductor substrate 1 to cover an upper surface of the insulator film 2, a top of the plug 7 of the refractory conductive material with in the small-diameter contact hole 4, a surface of the sidewall 6 of the refractory conductive material within the large-diameter contact hole 3, and a bottom of the large-diameter contact hole 3.

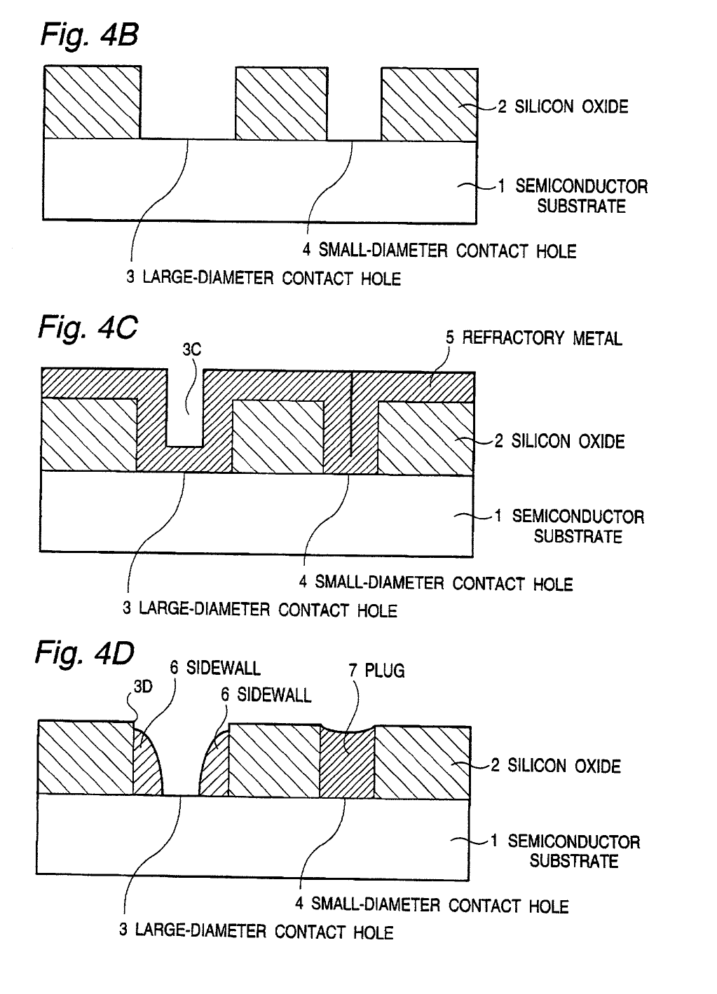

Now, the method for forming the contact structure shown in FIG. 3 will be explained with reference to FIGS. 4A to 4D.

As shown in FIG. 4A, a silicon oxide film 2 having a thickness of about 1 μm is formed on a principal surface of a silicon substrate 1 by a CVD process.

Then, as shown in FIG. 4B, a large-diameter contact hole 3 having a diameter of 0.8 μm and a small-diameter contact hole 4 having a diameter of 0.4 μm are formed to penetrate through the silicon oxide film 2, by use of a photolithography and an etching.

As shown in FIG. 4C, a refractory metal layer 5 is deposited on the whole surface of the silicon substrate 1. The refractory metal layer 5 is controlled to have a film thickness of for example about 300 nm. By forming the refractory metal layer 5 of about 300 nm, the small-diameter contact hole 4 is completed filled with the refractory metal, and on the other hand, the large-diameter contact hole 3 is filled with the refractory metal to partially leave a not-filled space 3C.

Thereafter, as shown in FIG. 4D, the deposited refractory metal layer 5 is etched back to such a degree that an upper surface of the silicon oxide film 2 is completely exposed, a bottom of the large-diameter contact hole 3 is partially exposed, and an upper end portion 3D of the large-diameter contact hole 3 is exposed. As a result, the small-diameter contact hole 4 is filled with a plug 7 of the refractory metal, and in the large-diameter contact hole 3, there is formed a sidewall 6 of the refractory metal, which covers a side surface of the large-diameter contact hole 3 lower than a position which is lower than an upper end of the large-diameter contact hole by a predetermined distance selected in the range of not less than 0.1 μm but not greater than 0.4 μm.

Then, an aluminum film 8 constituting a wiring conductor layer is deposited by for example a sputtering, to cover the whole surface of the substrate 1, as shown in FIG. 3. Thereafter, the aluminum film 8 is patterned to form a wiring conductor.

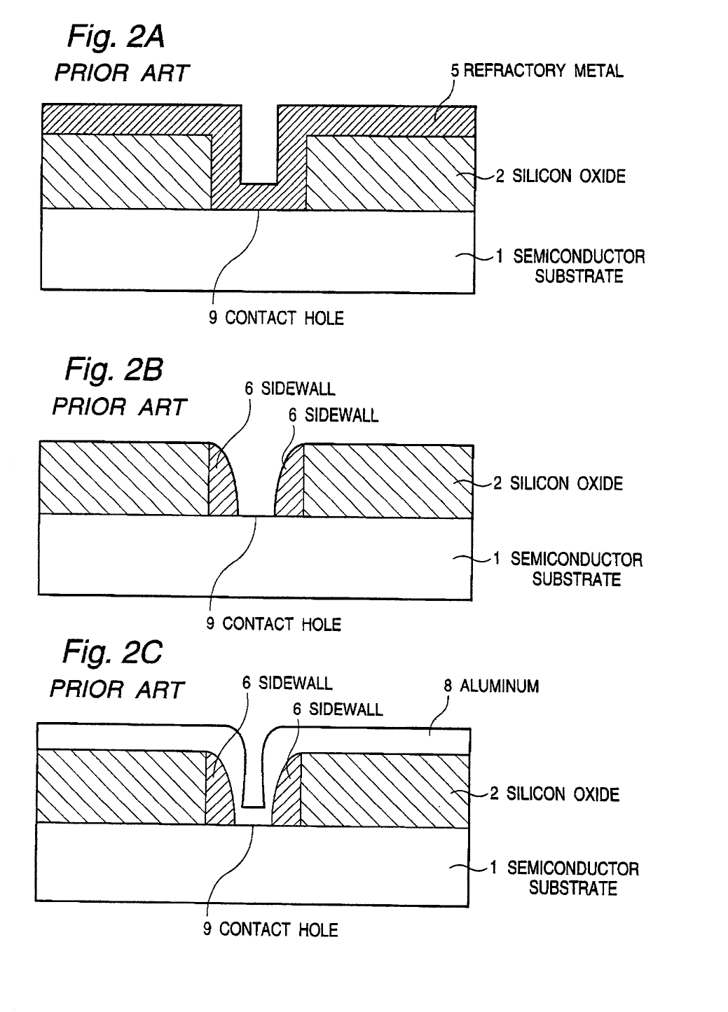

In this first embodiment, since the sidewall 6 of the refractory conductive material is formed to cover the side surface of the large-diameter contact hole 3 lower than the position which is lower than the upper end 3D of the large-diameter contact hole by the predetermined distance, a hole defined by the sidewall and the upper side surface of the contact hole has an upper end diameter larger than a bottom diameter, in other words, has a general shape which may be called a reverse-truncated cone. Namely, the hole defined by the sidewall and the upper side surface of the contact hole has an apparent the aspect ratio noticeably improved or reduced in comparison with the prior art as shown in FIG. 2B in which the sidewall reaches the upper end of the contact hole, with the result that the wiring conductor layer deposited in a later step is prevented from disconnecting at the bottom of the hole defined by the sidewall. Therefore, even if the interlayer insulator film becomes thick because of the advanced high integrated density and highly fine patterning of the semiconductor integrated circuit, the wiring conductor layer deposited within the large-diameter contact hole 3 is difficult to disconnect.

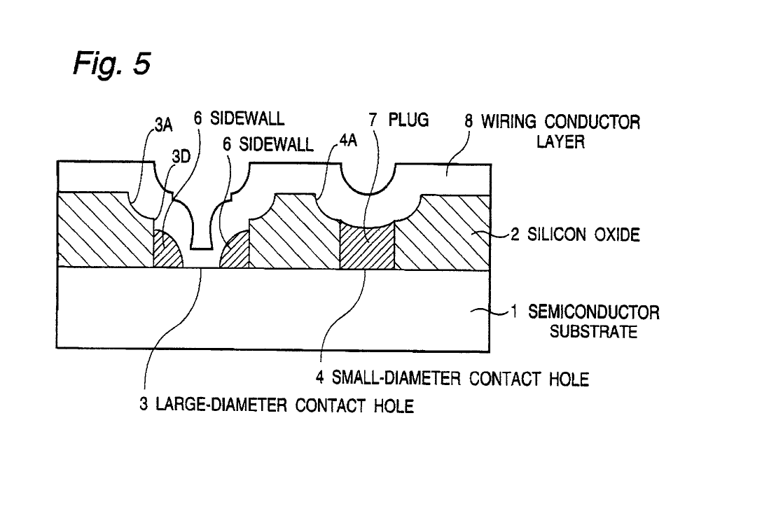

Referring to FIG. 5, there is shown a diagrammatic sectional view illustrating of a second embodiment of the contact structure in the semiconductor integrated circuit in accordance with the present invention. In FIG. 5, elements corresponding to those shown in FIG. 3 are given the same Reference Numerals.

The second embodiment of the contact structure includes a semiconductor substrate 1, an insulator film 2 formed on a semiconductor substrate 1, a large-diameter contact hole 3 formed to penetrate through the insulator film 2 and a small-diameter contact hole 4 formed to penetrate through the insulator film 2. The large-diameter contact hole 3 and the small-diameter contact hole 4 have a funnel-shaped portion 3A or 4A formed on an upper portion thereof to open or spread upward. Excluding the funnel-shaped portion 3A, the small-diameter contact hole 4 is completely filled with a plug 7 of a refractory conductive material. In the large-diameter contact hole 3, on the other hand, a sidewall 6 formed of the refractory conductive material covers a side surface of the large-diameter contact hole 3 lower than a position which is lower than, by a predetermined distance, a boundary 3D between a vertical side surface of the large-diameter contact hole 3 and the funnel-shaped portion 4A. Similarly to the first embodiment, the refractory conductive material is either a refractory metal or a silicide of the refractor metal. A wiring conductor layer 8 (formed of for example aluminum) is deposited on the whole surface of the semiconductor substrate 1 to cover an upper surface of the insulator film 2, a top of the plug 7 of the refractory conductive material within the small-diameter contact hole 4, the funnel-shaped portion 4A, a surface of the sidewall 6 of the refractory conductive material within the large-diameter contact hole 3, a bottom of the large-diameter contact hole 3, and the funnel-shaped portion 3A.

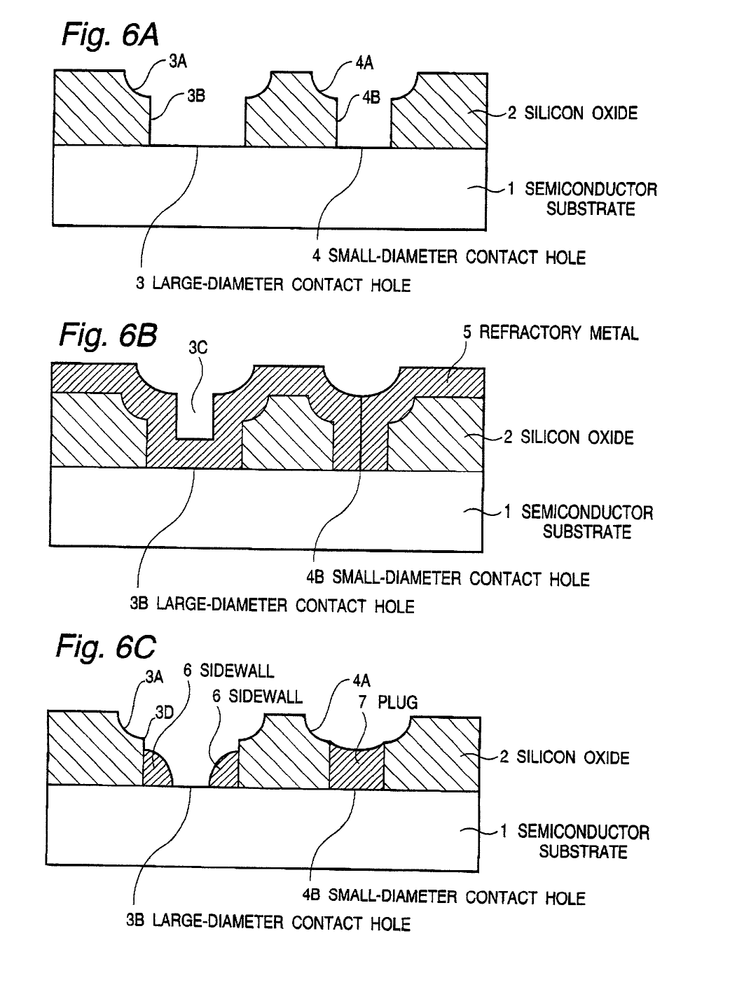

Now, the method for forming the contact structure shown in FIG. 5 will be explained with reference to FIGS. 6A to 6C.

The process is the same as the process of the first embodiment until the step shown in FIG. 4A in which the silicon oxide film 2 is formed.

Then, as shown in FIG. 6A, a large-diameter contact hole 3 having a diameter of 0.8 μm and a small-diameter contact hole 4 having a diameter of 0.4 μm are formed to penetrate through the silicon oxide film 2, by use of a photolithography and an etching. Furthermore, an upper portion of these contact holes is expanded to have the funnel-shaped portions 3A and 4A, respectively. A remaining portion of the large-diameter contact hole 3 having a vertical side surface, other than the funnel-shaped portion 3A, is designated with Reference Numeral 3B, and is called a large-diameter contact hole hereinafter, and a remaining portion of the small-diameter contact hole 4 having a vertical side surface, other than the funnel-shaped portion 4A, is designated with Reference Numeral 4B, and is called a small-diameter contact hole hereinafter.

Furthermore, as shown in FIG. 6B, a refractory metal layer 5 having a film thickness of for example about 300 nm is deposited on the whole surface of the silicon substrate 1 so that the small-diameter contact hole 4B and the funnel-shaped portion 4A are completed filled with the refractory metal, and on the other hand, and the funnel-shaped portion 3A and a bottom surface and a side surface the large-diameter contact hole 3B are completely covered with the deposited refractory metal 5, but the large-diameter contact hole 3B is partially filled with the deposited refractory metal to leave a not-filled space 3C at a central portion.

Thereafter, as shown in FIG. 6C, the deposited refractory metal layer 5 is etched back to such a degree that an upper surface of the silicon oxide film 2 and a surface of the funnel-shaped portions 3A and 4A are completely exposed and the bottom of the large-diameter contact hole 3B is partially exposed, and an upper end 3D of the large-diameter contact hole 3B is exposed.

As a result, the small-diameter contact hole 4B is completely filled with a plug 7 of the refractory metal, and in the large-diameter contact hole 3B, there is formed a sidewall 6 of the refractory metal, which covers a side surface of the large-diameter contact hole 3B lower than a position which is lower than the upper end 3D of the large-diameter contact hole 3B by a distance, which corresponds to the predetermined distance in the first embodiment, namely, which is in the range of not less than 10% but not greater than 40% of a thickness of the insulator film 2.

Then, an aluminum film 8 constituting a wiring conductor layer is deposited by for example a sputtering, to cover the whole surface of the substrate 1, as shown in FIG. 5. Thereafter, the aluminum film 8 is patterned to form a wiring conductor.

In this second embodiment, since the funnel-shaped portion 3A is formed to extend from the upper end of the large-diameter contact hole 3B and since the sidewall 6 of the refractory conductive material is formed to cover the side surface of the large-diameter contact hole 3B lower than the position which is lower than the upper end 3D of the large-diameter contact hole 3B by the predetermined distance, a hole defined by the funnel-shaped portion 3A, the large-diameter contact hole 3B and the sidewall 6 has an upper end diameter larger than a bottom diameter, in other words, has a general shape which may be called a reverse-truncated cone. In addition, this reverse-truncated cone has an inclination angle gentler than that of the reverse-truncated cone in the first embodiment. Namely, the contact hole has the apparent aspect ratio further improved or reduced in comparison with the first embodiment. Therefore, even if the interlayer insulator film becomes thick because of the advanced high integrated density and highly fine patterning of the semiconductor integrated circuit, the wiring conductor layer deposited within the large-diameter contact hole 3 is more difficult to disconnect, than the first embodiment.

As seen from the above, the contact structure in accordance with the present invention is characterized in that the small-diameter contact hole is completely filled with the refractory conductive material, and in the large-diameter contact hole, the sidewall formed of the refractory conductive material covers the side surface of the large-diameter contact hole lower than the position which is lower than the upper end of the large-diameter contact hole by the predetermined distance.

With this feature, even if the interlayer insulator film becomes thick or even if the contact hole becomes fine because of the advanced high integrated density and highly fine patterning of the semiconductor integrated circuit, the wiring conductor layer never disconnect at the bottom of the contact hole, with the result that the contact resistance is stable and low. Therefore, a small and stable contact resistance can be realized both in the large-diameter contact hole and in the small-diameter contact hole which are mixedly included in a semiconductor integrated circuit.

The invention has thus been shown and described with reference to the specific embodiments. However, it should be noted that the present invention is in no way limited to the details of the illustrated structures but changes and modifications may be made within the scope of the appended claims.

1. A semiconductor device including a large-diameter contact hole and a small-diameter contact hole formed to penetrate through an insulator film formed on a conductive portion to reach said conductive portion, said small-diameter contact bole being completely filled with a plug of a refractory conductive material, and said large-diameter contact hole having a sidewall formed of said refractory conductive material on a side surface of said large-diameter contact hole, said sidewall covering said side surface lower than a position which is lower than an upper end of said large-diameter contact hole by a predetermined distance, a wiring conductor layer being deposited on said insulator film to cover a top surface of said plug of said refractory conductive material, and to fill a space remaining in said large-diameter contact hole thereby to cover a bottom of said large-diameter contact hole and a surface of said sidewall of said refractory conductive material within said large-diameter contact hole.

2. A semiconductor device claimed in claim 1 wherein each of said large-diameter contact hole and said small-diameter contact hole has a funnel-shaped portion formed on an upper portion thereof to open or spread upward, a surface of said funnel-shaped portion being covered with said wiring conductor layer.

3. A semiconductor device claimed in claim 2 wherein said refractory conductive material is a material selected from the group consisting of a refractory metal and a silicide of a refractor metal.

4. A semiconductor device claimed in claim 1 wherein said large-diameter contact hole has an aspect ratio of not greater than 2, and said small-diameter contact hole has an aspect ratio of greater than 2.

5. A semiconductor device claimed in claim 4 wherein said predetermined distance is in the range of not less than 10% but not greater than 40% of a thickness of said insulator film.

6. A semiconductor device claimed in claim 1 wherein said predetermined distance is in the range of not less than 10% but not greater than 40% of a thickness of said insulator film.

7. A semiconductor device claimed in claim 1 wherein said refractory conductive material is a material selected from the group consisting of a refractory metal and a silicide of a refractor metal.

8. A semiconductor device in claim 7 wherein said large-diameter contact hole has an aspect ratio of not greater than 2, and said small-diameter contact hole has an aspect ratio of greater than 2.

9. A semiconductor device claimed in claim 8 wherein said predetermined distance is in the range of not less than 10% but not greater than 40% of a thickness of said insulator film.

10. A semiconductor device claimed in claim 7 wherein said predetermined distance is in the range of not less than 10% but not greater than 40% of a thickness of said insulator film.
